(19) United States
(12) Patent Application Publication
(10) Pub. No.: US 2026/0301790 A1
(43) Pub. Date: Oct. 1, 2026

(54) APPARATUSES SYSTEMS AND METHODS FOR HOT ELECTRON INDUCED PUNCH-THROUGH DEGRADATION MITIGATION

(71) Applicant: Micron Technology, Inc., Boise, ID (US)

(72) Inventor: Erik T. Barmon, Boise, ID (US)

(73) Assignee: Micron Technology, Inc., Boise, ID (US)

(21) Appl. No.: 19/541,876

(22) Filed: Feb. 17, 2026

Related U.S. Application Data
(60) Provisional application No. 63/777,086, filed on Mar. 25, 2025.

(51) Int. Cl. G11C 11/403; G11C 11/408

(52) U.S. Cl. CPC G11C 11/403; G11C 11/4085; G11C 11/4087

(57) ABSTRACT

A memory device undergoes hot electron induced punch-through (HEIP) degradation in the transistors of its sub-word line drivers. The memory device may identify sets of sub-word line drivers which have undergone HEIP degradation. For example, the memory may include a register which stores FX addresses and count values. When the row decoder provides a row address, the FX portion of the row address is compared to the stored FX addresses. If there is a match, the count value is updated. Once the updated count value crosses a threshold, the associated stored FX address is identified for HEIP refreshing. The memory may perform HEIP refreshes by activating the word lines which share the FX address in common.

### CROSS REFERENCE TO RELATED APPLICATION(S)

This application claims the benefit under 35 U.S.C. § 119 of the earlier filing date of U.S. Provisional Application Ser. No. 63/777,086 filed Mar. 25, 2025 the entire contents of which is hereby incorporated by reference in its entirety for any purpose.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received along with address information which specifies which memory cells should be accessed.

When memory cells are accessed, various voltages may be driven along conductive elements. For example, sub-word line drivers may activate a word line by driving a voltage along it. The transistors in the drivers may degrade over time through a process known as hot electron induced punch-through (HEIP). Over long time periods, HEIP will negatively affect the operation of the transistors and thus the drivers formed from those transistors and the various operations those drivers control. It may be useful to monitor HEIP in order to mitigate it.

### BRIEF DESCRIPTION OF THE DRAWINGS

FIG. 1 is a block diagram of a semiconductor device according to some embodiments of the disclosure.

FIG. 2 is a block diagram showing a layout of an example portion of a memory bank according to some embodiments of the present disclosure.

FIG. 3 is a schematic diagram showing an example portion of a memory bank according to some embodiments of the present disclosure.

FIG. 4 is a block diagram of a bank logic with HEIP tracking and mitigation according to some embodiments of the present disclosure.

FIG. 5 is a timing diagram of a HEIP refresh operation being performed along with regular refresh operations according to some embodiments of the present disclosure.

FIG. 6 is a schematic diagram of multiple HEIP refresh operations being performed together according to some embodiments of the present disclosure.

FIG. 7 is a flow chart of a method of tracking HEIP degradation according to some embodiments of the present disclosure.

FIG. 8 is a flow chart of a method of performing HEIP refresh operations according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

Certain transistors in a memory may be particularly prone to HEIP degradation. HEIP degradation may occur when a p-type transistor, such as a PMOS, is in its off state (e.g., with a high voltage applied to its gate) and there is a relatively high voltage differential between the source and the drain terminals. For example, the transistors in sub-word line drivers (SWDs) may be particularly prone to HEIP over time. A row decoder decodes the row address into a MWL address and a FX address, which together specify a SWD. A group of SWDs are coupled to a common voltage line which is activated by the FX address. The MWL address then specifies one of those SWDs which activates a word line. Accordingly, when a word line is accessed, all the SWDs coupled to the specified FX line have a high voltage applied across their terminals, but only the one of that set specified by the MWL address will be in its on state (e.g., with a low voltage applied to its gate). Accordingly, transistors in the SWDs specified by FX but not specified by MWL may be prone to HEIP degradation. It may be useful to mitigate HEIP degradation in the SWD drivers.

The present disclosure is drawn to apparatuses, systems, and methods for HEIP degradation mitigation. In some embodiments, the present disclosure may include monitoring and identifying locations of HEIP degradation and repairing HEIP degradation. A memory device may track HEIP degradation by tracking FX activations. For example, the memory device may count activations of FX addresses and identify SWDs as needing HEIP mitigation based on the count. For example, the memory may include a register that stores some number of FX addresses along with an associated count. When an access operation is performed, the FX address for that access operation is compared to FX addresses stored in the register. If there is a match, the count value for that stored FX address is changed (e.g., incremented). If there is not a match, the FX address may be added, for example replacing the FX address in the register with the lowest count. In some embodiments, if one of the counts crosses a threshold, then HEIP mitigation may be performed on the SWDs which share that FX address. In some embodiments, when HEIP mitigation is called for, the FX address with the highest count may be mitigated.

In some embodiments, the present disclosure may include HEIP mitigation. While HEIP may build up over time, and may persist even when the device is powered off, it is possible to reverse HEIP by activating the transistor for a relatively long time. The memory device may perform HEIP mitigation operations by generating a HEIP refresh address for one of the word lines which is expected to suffer from HEIP degradation and activating that word line for a relatively long period of time. For example, refresh operations may be performed during a time period tRFC and during that time period one or more word lines may be activated for a relatively short period of time. The row where a HEIP refresh is being performed is activated for all or most of tRFC.

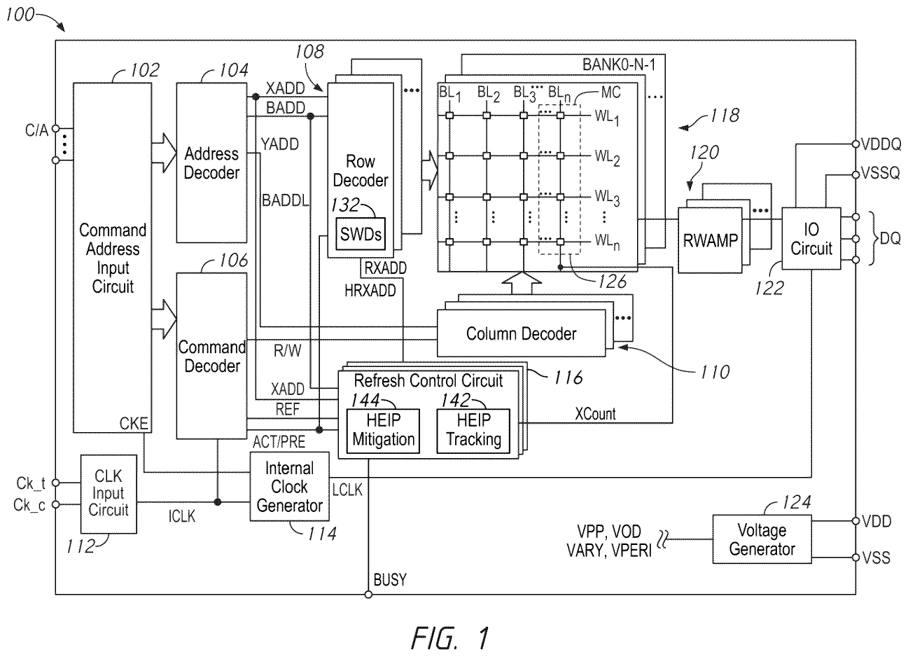

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. In some embodiments, the semiconductor device 100 may represent a stand-alone memory device.

The semiconductor device 100 includes a memory array 118. The memory array 118 is organized into a plurality of memory banks. In the embodiment of FIG. 1, the memory array 118 is shown as including N memory banks labeled BANK0 to BANKN-1. For example, a memory array 118 may include 4, 8, 16, 32 or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. For example, the row address XADD may be decoded into signals which selectively activate a sub-word line driver 132 each of which is coupled to a word line. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, access commands for accessing the memory, such as row activation commands, read commands for performing read operations, write commands for performing write operations, and pre-charge commands, refresh commands such as all-bank refresh, same bank refresh, and per-bank refresh, as well as other commands and operations. The access commands may be associated with one or more row address XADD, column address YADD, and bank address BADD to indicate the memory cell(s) to be accessed. In some embodiments, the command and address may be transmitted together as a command packet along the C/A terminals. The input circuit 102 separates the command portion of the packet from the address portion and provides the command portion to the command decoder 106 and the address portion to the address decoder 104.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal row activation command or internal row activation signal ACT. Responsive to a pre-charge command the command decoder 106 provides an internal pre-charge command or internal pre-charge signal Pre. The row decoder 108 activates a word line responsive to the internal activation signal ACT and deactivates (or pre-charges) the word line responsive to the internal pre-charge signal Pre. For example responsive to the activation signal and a row address XADD, the row decoder 108 selects a sub-word line driver 132 and activates the selected sub-word line driver

In an example write operation, the device 100 writes data received at the DQ terminals to the memory cells specified by a received bank, row and column address. As part of the write operation, the command decoder 106 receives a write command and activation command and provides internal signals such as W and ACT/Pre. The write data is received by the IO circuit 122 and provided to the RWAMP circuit 120. The row decoder 108 selected by BADD activates the row selected by XADD responsive to the internal activation signal ACT. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line.

In an example read operation, the device 100 reads data from the memory cells specified by a received bank, row, and column address and provides that read data to the DQ terminals. As part of the read operation, the command decoder 106 receives a read command and an activation command and provides internal signals such as a read signal R, and ACT/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals.

The device 100 includes refresh control circuits 116 each associated with a bank of the memory array 118. Each refresh control circuit 116 performs refresh operations on the associated bank by providing a refresh address RXADD, along with one or more refresh signals. The refresh address RXADD may be generally similar to a row address and may specify one or more word lines. The refresh control circuits 116 may perform one or more refresh operations responsive to a refresh command. For example, the memory may receive an all-bank refresh command REFab along the C/A terminals, and the command decoder 106 provides a refresh signal REF to all of the refresh control circuits 116. Responsive to the refresh signal REF, the refresh control circuits 116 perform refresh operations. The memory may also receive commands such as a per-bank refresh command REFpb or same-bank refresh command REFsb, which specify which bank or banks the command decoder 106 should provide the refresh signal to.

Refresh operations may include one or more normal refresh operations, one or more targeted refresh operations, or combinations thereof. In a normal refresh operation, the refresh address is generated based on sequence logic. For example a refresh address counter may increment to generate a new refresh address, such as RXADD(i)=RXADD(i−1)+1. In a targeted refresh operation, an identified aggressor address is used to generate refresh addresses. The refresh addresses may be adjacent to the aggressor, for example RXADD=Aggressor+/−1.

The refresh control circuit 116 also tracks accesses to word lines of the respective banks to determine if a targeted refresh operation should be performed. Memory cells along each word line are set aside as counter memory cells 126. The counter memory cells store a per-row access count (PRAC) value associated with a number of times that the respective word line has been accessed. When a word line is accessed or refreshed, its PRAC value is read out to the refresh control circuit 116 which updates (e.g., increments) the count value and determines if the count has crossed a threshold as part of an access count update (ACU) operation. If the PRAC value has crossed a mitigation threshold, then the address is added to an aggressor queue for a later targeted refresh operation. When a targeted refresh operation is performed, one or more victim word lines of the aggressor word line are refreshed.

The refresh control circuit 116 includes a HEIP mitigation circuit 144. The HEIP mitigation circuit is used by the refresh control circuit 116 to perform HEIP refresh operations. During a HEIP refresh operation, the refresh control circuit generates a HEIP refresh address HRXADD and provides it to the row decoder 108. Responsive to HRXADD along with one or more other signals indicating a HEIP refresh operation, the row decoder 108 performs HEIP mitigation on the specified SWD 132 by activating the word line specified by HRXADD for a HEIP recovery time. The HEIP recovery time may be relatively long, for example the entire length tRFC over which the memory performs multiple refresh operations.

The refresh control circuit 116 may optionally include a HEIP tracking circuit 142 which is used to detect when to perform HEIP refresh operations and/or which word line/word lines should have HEIP refresh operations performed on them. For example, the HEIP tracking circuit 142 may include a register which saves row addresses, or portions thereof, along with counts associated with the stored addresses. The counts may track a number of times that rows which share a common FX address portion of the row address are accessed. In some embodiments, when the count crosses a threshold, it may be flagged as requiring a HEIP refresh, and the HEP mitigation circuit 144 may generate HEIP refresh addresses for all the row addresses that share that FX address portion in common.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks. The voltages VDD and VSS (or voltages derived therefrom) may generally be used by circuits of the memory such as the array 118, row decoder 108, refresh control circuit 116 and others. The voltages VDDQ and VSSQ may generally be used by the input/output circuit 122 and not by other components of the memory device 100.

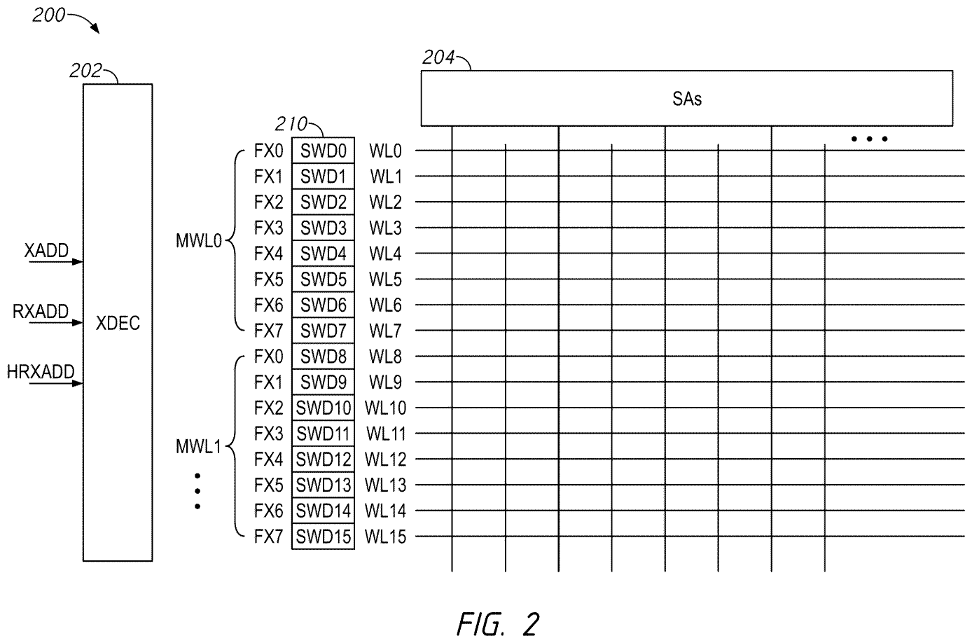

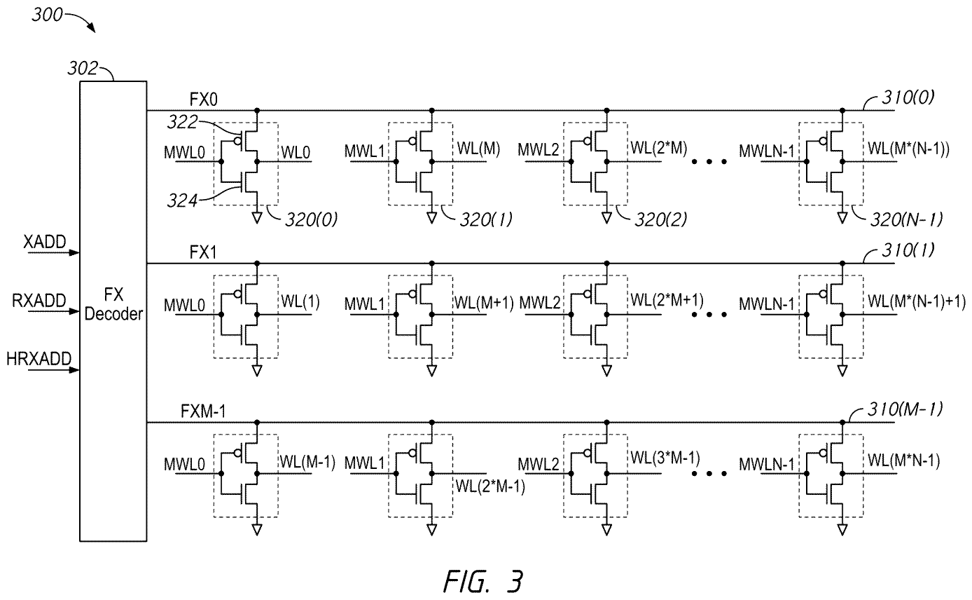

FIGS. 2 and 3 show examples of sub-word line driver control in an example portion of a memory bank. FIG. 2 shows an example layout of the portion of the memory bank and is used to represent the physical arrangement of how signals can be used to activate word lines. FIG. 3 shows a schematic diagram that shows how different signals are used to activate SWDs.

FIG. 2 is a block diagram showing a layout of an example portion of a memory bank according to some embodiments of the present disclosure. The portion of the memory bank 200 may, in some embodiments, implement a portion of the array 118 of FIG. 1 along with associated circuitry like the row decoder 202 (e.g., row decoder 108 of FIG. 1), SWDs 210 (e.g., 132 of FIG. 1) and sense amplifiers 204.

The row decoder 202 receives addresses such as row addresses XADD, refresh addresses RXADD, and HEIP refresh addresses HRXADD. The various addresses XADD, RXADD, and HRXADD may be generally similar to each other. For example, each is a string of bits which specifies one or more word lines. In some embodiments, address XADD may specify a single word line, while the refresh address RXADD and/or HRXADD may mask one or more bits such that they specify more word lines than the address XADD. The row address XADD and how it is decoded will be described in detail, however unless otherwise noted that description will also generally apply to addresses like RXADD and HRXADD.

The row address XADD includes a FX address and a MWL address. The row decoder 202 decodes the FX address into an FX signal and the MWL address into an MWL signal. The FX signal and MWL signal together specify a SWD 210, which is coupled to a word line. In this example, 16 word lines WL0 to WL16 are shown along with their associated SWDs 210 SWD0 to SWD15.

In the example implementation of FIG. 2, the FX address decodes into 8 possible FX signal values FX0 to FX7. For example, the FX address may be 3 bits. The FX signal may be shared across multiple SWDs 210. The MWL signals may be associated with multiple SWDs 210. In the example implementation of FIG. 2, there are 8 SWDs for each MWL signal. For example, MWL0 is associated with SWDs 0 to 7, MWL1 is associated with SWD8 to SWD15 and so forth. Responsive to the FX signal, the SWDs which share that FX signal in common may be powered. Responsive to the MWL signal, the one of the SWDs associated with that MWL signal which is powered will be activated. For example, if the row address decodes to MWL0 and FX4, then both SWD4 and SWD12 will be powered (along with other word lines, not shown) but only SWD4 will be activated.

FIG. 3 is a schematic diagram showing an example portion of a memory bank according to some embodiments of the present disclosure. The portion 300 may, in some embodiments, represent an implementation of the array 118 and SWDs 132 of FIG. 1 and/or the array 200 and SWDs 210 of FIG. 2. The portion 300 shows an FX decoder 302, which is a portion of a row decoder (e.g., 108 of FIG. 1 and/or 202 of FIG. 2) and associated sets of SWDs 320.

The FX decoder 302 provides FX signals along FX lines 310 based on a decoded row address. Each of the FX lines 310 is coupled to a set of SWDs 320. When the FX signal is active, a relatively large system voltage, such as Vccp is driven along the corresponding FX line 310. Each SWD is coupled to a MWL signal and a word line. In the example implementation of FIG. 3, there are N SWDs (and N word lines) coupled to each FX line 310. Accordingly, there are N different MWL values. There are M different FX signal values, and thus M different FX signal lines 310, for a total of N×M SWDs 320.

Each SWD 320 includes a pair of transistors 322 and 324. The first transistor 322 is a p-type transistor with terminals coupled between the FX line 310 and the word line. The second transistor 324 is an n-type transistor with terminals coupled between the word line and a ground voltage. The gates of the two transistors 322 and 324 are coupled to a corresponding MWL signal. Accordingly, when the MWL signal may be active at a low voltage level, which in turn will activate first transistor 322 and deactivate the second transistor 324. When the MWL signal is active, the SWDs 320 coupled to that MWL signal will couple the corresponding WL to the corresponding FX line 310, but only the FX line which is active will then activate the WL. Similarly, when an FX signal is active, all the SWDs 320 coupled to that FX signal line 310 will have a high voltage applied to the source terminals of their first transistor 322, but only the SWD 320 associated with the MWL signal will be activated. In this way, the first transistors 322 of the non-activated SWDs 320 coupled to an FX signal line 310 will have a relatively large voltage difference between their source and drain terminals and may be subject to HEIP.

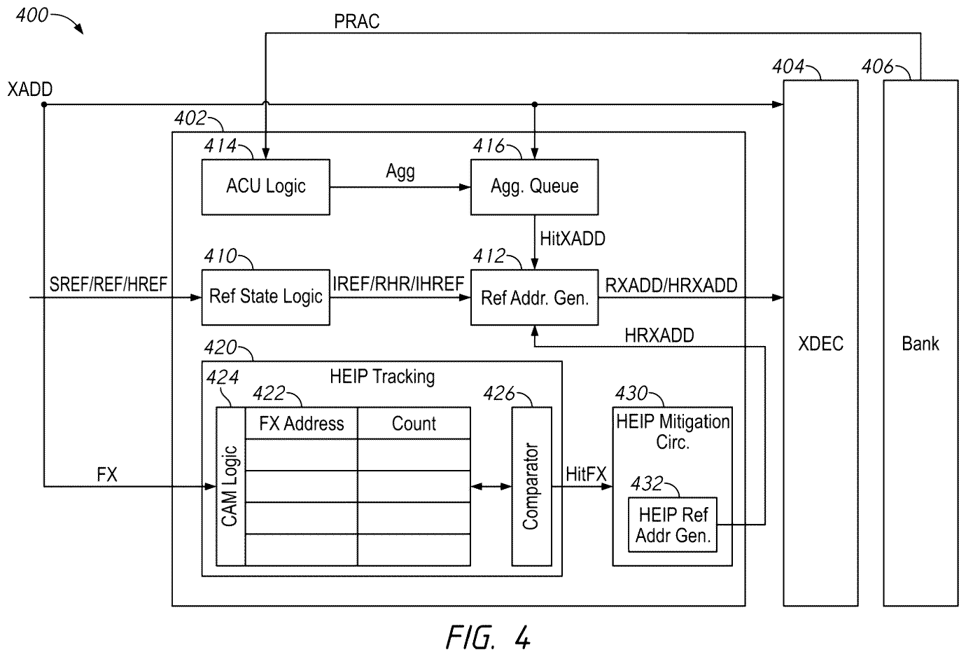

FIG. 4 is a block diagram of a bank logic with HEIP tracking and mitigation according to some embodiments of the present disclosure. The bank logic 400 of FIG. 4 may represent a portion of a memory device, such as 100 of FIG. 1. In particular, the bank logic 400 shows certain components that may be used to perform refresh operations, such as HEIP refresh operations, on a bank. The bank logic 400 shows components that may generally be repeated on a bank-by-bank basis. The bank logic 400 includes a refresh control circuit 402 (e.g., 116 of FIG. 1), a row decoder 404 (e.g., 108 of FIG. 1, 202 of FIG. 2, and/or 302 of FIG. 3) and a bank (e.g., 118 of Figure or bank portions 200 of FIG. 2 and/or 300 of FIG. 3).

The refresh control circuit 402 manages refresh operations in the associated memory bank 406. When a refresh operation is performed, the refresh control circuit 402 provides one or more refresh addresses RXADD and/or HEIP refresh addresses HRXADD along with one or more signals indicating a refresh operation to the row decoder 404, which refreshes the word line or word lines associated with the refresh address(es) RXADD/HRXADD.

The refresh control circuit 402 performs regular refresh operations by providing RXADD, HEIP refresh operations by providing HRXADD, or a combination thereof. The regular refresh operations include normal refresh operations that sequentially refresh word lines of the bank 406 and targeted refresh operations, that refresh one or more word lines targeted for refreshing outside the usual sequence. For example, the targeted refresh operations may be performed on word lines which have a physical relationship (e.g., adjacency) to word lines which are frequently accessed. The HEIP refresh operations may be somewhat analogous to the targeted refresh operations, in that they are performed on specifically identified word lines based on frequent accesses. However the process of refreshing the word lines during a HEIP refresh operation may be different than the process of refreshing a word line during a targeted refresh operation.

The refresh control circuit 402 includes a refresh state logic circuit 410 which determines whether a normal or targeted refresh operation should be performed. The refresh state logic circuit 410 receives refresh signals such as REF or SREF or an HEIP refresh signal HREF. The refresh signal REF may be generated responsive to a refresh command. The self-refresh signal SREF may be generated periodically by an oscillator circuit of the memory device during a self-refresh mode. The signal HREF may be generated responsive to an HEIP refresh command. The refresh state logic circuit 410 generates one or more internal refresh signals IREF and RHR responsive to REF/SREF and generates an internal HREF signal IHREF responsive to the HEIP refresh signal HREF. The signal IREF indicates a normal refresh operation, the signal RHR (or RHR and IREF together) indicates a targeted refresh operation. The refresh state logic circuit 410 may generate several activations of IREF, RHR, or combinations thereof responsive to REF or SREF. In some embodiments, the refresh state logic circuit 410 may additionally provide an internal HEIP refresh signal IHREF when a HEIP refresh operation is called for. In some embodiments, the HEIP mitigation circuit 430 may generate HEIP refresh signals.

A refresh address generator circuit 412 generates the refresh addresses RXADD. Responsive to a normal refresh operation, the refresh address generator circuit 412 generates RXADD using sequence logic. For example, responsive to IREF (or to IREF alone) the refresh address generator circuit 412 may include a refresh address counter circuit, and the counter may be incremented to generate a next refresh address RXADD. Responsive to a targeted refresh operation, the refresh address generator circuit 412 generates refresh addresses based on addresses in an aggressor queue 416. For example, responsive to RHR (or to IREF and RHR together) the refresh address generator circuit 412 retrieves an aggressor address HitXADD from the queue 416 and generates RXADD as one or both of the row addresses of word lines adjacent to HitXADD. Responsive to the internal HEIP refresh signal IHREF, the refresh address generator circuit 412 provides a HEIP refresh address HRXADD provided by the HEIP mitigation circuit 430.

The refresh control circuit 402 includes access count update (ACU) logic circuits 414, which manage ACU operations. When a word line is accessed, its access count value PRAC is read out to the ACU logic circuits 414. For example, the access count PRAC may be read out from counter memory cells (e.g., 126 of FIG. 1) along the accessed word line. The ACU logic circuit 414 receives the PRAC value, updates it, and writes the updated value back to the bank 406. For example, the PRAC value may be incremented as part of the ACU operation. The ACU logic circuit 414 compares the updated PRAC value to a mitigation threshold. If the updated PRAC value has crossed the mitigation threshold, the ACU logic circuit 414 provides an aggressor detected signal AGG. Responsive to the signal AGG, the aggressor queue 416 stores the current row address XADD as an aggressor.

The refresh control circuit 402 includes a HEIP tracking circuit 420. The HEIP tracking circuit monitors accesses to the word lines to determine which SWDs may require HEIP refresh operations. For example, the HEIP tracking circuit 420 may monitor FX addresses, since each time a word line is accessed, the other SWD's along that same FX line (e.g., 310 of FIG. 3) may experience HEIP degradation.

In an example implementation, the HEIP tracking circuit 420 receives the FX address portion of the row address XADD along the row address bus. The FX address may be a subset of the bits of the row address XADD. The FX address specifies the FX line to be activated. The HEIP tracking circuit 420 includes a register 422. The register stores a number of stored FX addresses and a number of count values, each associated with one of the stored FX addresses. The register 422 may be organized into a number of slots, each with a field for an FX address and a field for its associated count value. For example, the register 422 may be implemented using content addressable memory (CAM) cells.

The register 422 has associated register logic 424 which manages the contents of the register 422. When an FX address is received, the register logic 424 compares the FX address to the stored addresses. If there is a match, the register logic 424 updates the count value associated with the matching address, for example, by incrementing the count value. If there is not a match, then the FX address is added to the register 422 as a new stored address. If there is an open slot, then the FX address is stored in that slot. If there is not an open slot, then the register logic 424 searches for the slot with the lowest count value and overwrites the address in that slot with the new FX address. In some embodiments, when an address is overwritten, the count value may be reset (e.g., to 0).

In some embodiments, when the register logic 424 updates the count value associated with the matching address, it may update the count by more than one. For example, the register logic 424 may take other factors into account that affect the speed at which HEIP degradation occurs. In some embodiments, the register logic 424 may take the time the FX address is active into account, for example by incrementing the count value every time a certain amount of time (e.g., a number of clock cycles) elapses. In some embodiments, the register logic 424 may take temperature into account, for example by receiving a temperature signal from a temperature sensor and changing the count value by an amount based on the temperature signal. In some embodiments, the register logic 424 may take both time and temperature into account, for example by increasing the count by an amount based on the temperature signal every time a certain amount of time elapses.

The HEIP tracking circuit 420 includes a comparator circuit 426 which compares the stored count values to a threshold. When one of the counts crosses the threshold (e.g., is greater than or equal to the threshold), the HEIP tracking circuit 420 identifies that a HEIP refresh operation is called for. The address associated with the count that crossed the threshold is identified as a HEIP degraded FX line address HitFX. Depending on the example implementation, the HEIP circuit 420 may take one or more actions. In some embodiments, HEIP refresh operations may be regularly performed, and the HEIP tracking circuit 420 may wait until one of those is performed and provide the identified address HitFX. In some embodiments, the HEIP tracking circuit 420 may signal the refresh state logic 410 that a HEIP refresh should be performed, for example by providing HREF, and the refresh state logic circuit 410 may then perform a HEIP refresh operation at the next opportunity. In some embodiments, the HEIP tracking circuit 420 may signal a controller of the memory device, and the controller may send commands to perform HEIP refresh operations, which may cause the signal HREF to be sent to the refresh state logic 410.

When a HEIP refresh operation is performed, the HEIP mitigation circuit 430 generates a HEIP refresh address HRXADD as well as one or more signals (not shown) to indicate a HEIP refresh operation. The HEIP mitigation circuit 430 includes a HEIP refresh address generator circuit 432 which generates a sequence of HEIP refresh addresses HRXADD based on the identified HEIP degraded FX line address HitFX from the HEIP tracking circuit 420. For example, the HEIP mitigation circuit 430 may perform HEIP refresh operations on each row address that has HitFX in common. In other words, addresses may be generated for each of the word lines, and each of the sub-word line drivers, coupled to the FX line identified by the address HitFX. For example, referring back to the numbering scheme of FIG. 3, the HEIP mitigation circuit 430 will perform HEIP refresh operations for HitFX+MWL0, HitFX+MWL1, . . . HitFX+MWLN-1. Referring back to the example layout of FIG. 2, if FX1 is identified as being the HEIP degraded FX line address HitFX, then the HEIP mitigation circuit 430 may perform a first HEIP refresh operation by generating an HRXADD for SWD1 (e.g., MWL0+FX1), then a second HEIP refresh operation by generating a HRXADD for SWD9 (e.g., MWL1+FX1) and so forth. In some embodiments, once HEIP refresh operations have been performed on each of the addresses associated with HitFX, the address HitFX may be removed from the register 422 and its count value reset. In some embodiments, once the HEIP refresh operations have been performed on each of the addresses associated with HitFX, the count associated with the address HitFX may be decreased by some amount.

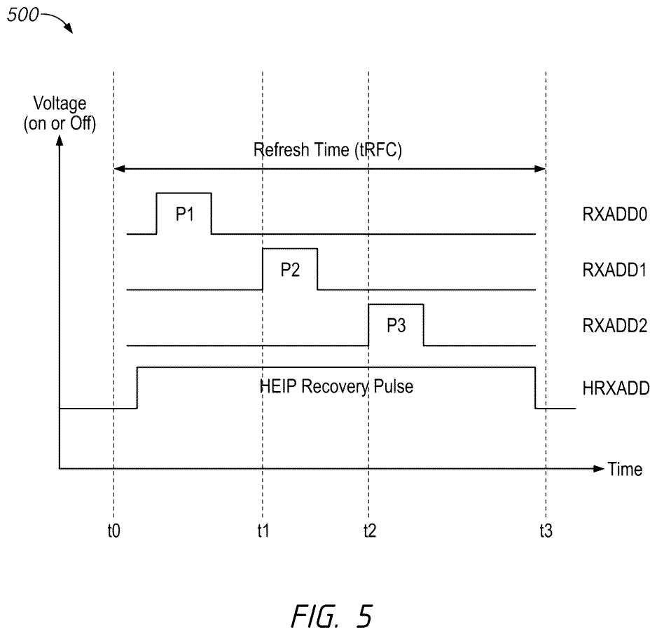

The refresh address generator circuit 412 receives the HEIP refresh addresses HRXADD and, in some embodiments, coordinates the HEIP refresh operations with other refresh operations. For example, in some embodiments, the HEIP mitigation circuit 430 may perform one or more HEIP refresh operations when other refresh operations are being performed. For example, responsive to IREF and/or RHR, the HEIP mitigation circuit 430 may perform one or more HEIP refresh operations if there is an identified HitFX address. An example operation where HEIP refreshes are performed while other refreshes are being performed is described in more detail in FIG. 5.

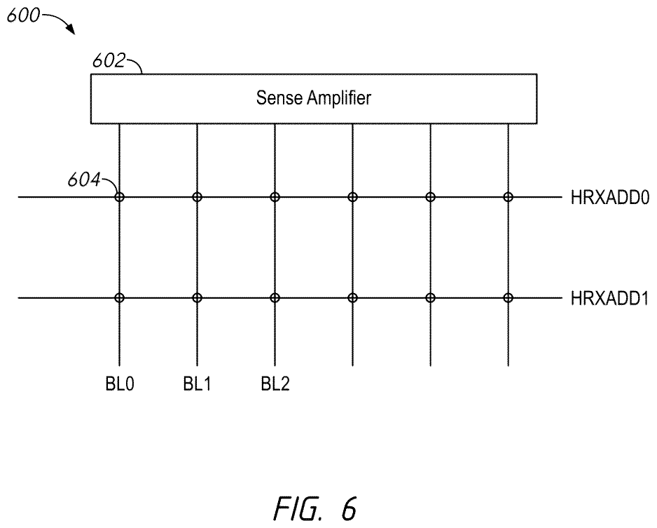

In some embodiments, the HEIP mitigation circuit 430 may perform one or more HEIP refresh operations as part of a HEIP refresh mode. In some embodiments, the controller may enter and exit the memory device into a HEIP refresh mode. In some embodiments, the HEIP refresh mode may be performed automatically when the memory is in a certain state. For example, if the memory is installed in a mobile device, then the HEIP refresh mode may be entered when the device is charging overnight. In some embodiments, the memory device may request that it be placed in a HEIP refresh mode. For example, the memory may raise a HEIP refresh flag to notify the controller that it should be placed in the HEIP refresh mode. During a HEIP refresh mode, the memory device may perform multiple HEIP refreshes. An example HEIP refresh mode operation is described in more detail in FIG. 6.

FIG. 5 is a timing diagram of a HEIP refresh operation being performed along with regular refresh operations according to some embodiments of the present disclosure. The timing diagram 500 shows an example implementation where a HEIP refresh operation is performed while other refresh operations are being performed. The timing diagram shows a number of traces which represent refresh operations on different rows over time. Each trace shows an example voltage applied to a word line. Three refresh operations, each associated with refresh addresses RXADD0, RXADD1, and RXADD2 are refreshed as part of standard refresh operations (e.g., normal or targeted refresh operations). Each of the refresh addresses RXADD0, RXADD1, RXADD2 may be associated with one or more word lines. An additional word line, associated with a HEIP refresh address HRXADD has a HEIP refresh operation performed on it.

Refresh operations begin at an initial time t0. For example, the device may receive a refresh command. At t0 the device begins performing refresh operations for a time period tRFC. For example if a controller sends a refresh command, it may wait the time tRFC before sending a subsequent command. At the time t0, the device performs a regular refresh at a first refresh address RXADD0, and also begins performing a HEIP refresh operation on the HEIP row. For example, a refresh address generator (e.g., 412 of FIG. 4) may provide the refresh address RXADD0 which indicates one or more word lines. A HEIP refresh address generator (e.g., 432 of FIG. 4) generates the HEIP refresh address HRXADD which indicates the HEIP row. The refresh of RXADD0 involves activating the associated word line(s) for a relatively short pulse. At a first time t1, the word line(s) of RXADD0 are no longer being refreshed and a second regular refresh operation is performed by the refresh address generator providing a next refresh address RXADD1. The HEIP row associated with HRXADD is still active at t1 as part of the HEIP refresh operation. At a second time t2, the word line(s) associated with RXADD1 are no longer being refreshed and a third regular refresh operation is performed by the refresh address generator providing a next refresh address RXADD2. The HEIP row associated with HRXADD is still active at t2 as part of the HEIP refresh operation. At a third time t3, the time tRFC has elapsed, and the HEIP refresh operation ends. More or fewer regular refresh operations per tRFC may be performed in other example embodiments. In some embodiments, some of the refresh operations may be normal refresh operations and others may be targeted refresh operations within the same tRFC.

Since multiple word lines are active at once, such as the word line(s) associated with RXADD0 and the word line associated with HRXADD at t0, during the refresh operations of FIG. 5, the refresh control circuit (e.g., 116 of FIG. 1 and/or 402 of FIG. 4) may include logic (e.g., in the refresh address generator and/or HEIP refresh address generator circuits) which prevents conflicts between the rows being refreshed. For example, the HEIP refresh address HRXADD may be chosen such that it is in a different section of the array than the refresh row addresses RXADD0, RXADD1, and RXADD2. The section containing the word line indicated by HRXADD may not share sense amplifiers with the section or sections containing the word lines indicated by RXADD0, RXADD1, and RXADD2. For example, the HEIP refresh address HRXADD may be in a section which is non adjacent to the section(s) which contain the word lines indicated by RXADD0, RXADD1, and RXADD2.

FIG. 6 is a schematic diagram of multiple HEIP refresh operations being performed together according to some embodiments of the present disclosure. FIG. 6 shows a simplified view of a portion of a memory array 600. The memory array 600 may, in some embodiments, represent portion of the array 118 of FIG. 1, 200 of FIG. 2, 300 of FIG. 3, and/or the bank 406 of FIG. 4. In particular, the view of the memory array 600 shows a section of the array where two HEIP refresh operations are happening at the same time.

The array includes sense amplifiers 602, which are coupled to bit lines BL0, BL1, BL2 and so forth. Memory cells 604 are positioned at the intersection of those bit lines with word lines. Two example word lines are shown, each corresponding to a HEIP refresh address HRXADD0 and HRXADD1. For the sake of illustration the two word lines are shown adjacent to each other, although that does not necessarily need to be the case. Similarly, the operation of FIG. 6 is described with respect to two HEIP refresh operations being performed at the same time, but more HEIP refreshes may be performed in other example embodiments.

In some embodiments, the memory device may have an opportunity to more aggressively perform HEIP refresh operations. For example, when the memory device is in a HEIP refresh mode, it may have more time to perform HEIP refresh operations than when it is performing them at the same time as regular refresh operations. Instead or in addition, in some situations, the memory may have the opportunity to perform HEIP refresh operations without needing to maintain data integrity along the refreshed word lines.

FIG. 6 shows example HEIP refresh operations in a HEIP refresh mode where multiple word lines are refreshed at the same time in a same section of the array. For example the HEIP mitigation circuit (e.g., 430 of FIG. 4) provides multiple HEIP refresh addresses such as HRXADD0 and HRXADD1. Since the two word lines share bit lines (and sense amplifiers 602), any data in the memory cells 604 may be corrupted. Accordingly, the multiple refreshes of FIG. 6 may occur at a time and/or in a location where it is not necessary to preserve data integrity. In addition, or instead, when the HEIP refresh mode is used at a time when memory operations are not generally occurring (e.g., when the device is in a sleep mode or otherwise not expected to be used), the HEIP refresh operations may be performed for a long period of time, such as much longer than tRFC.

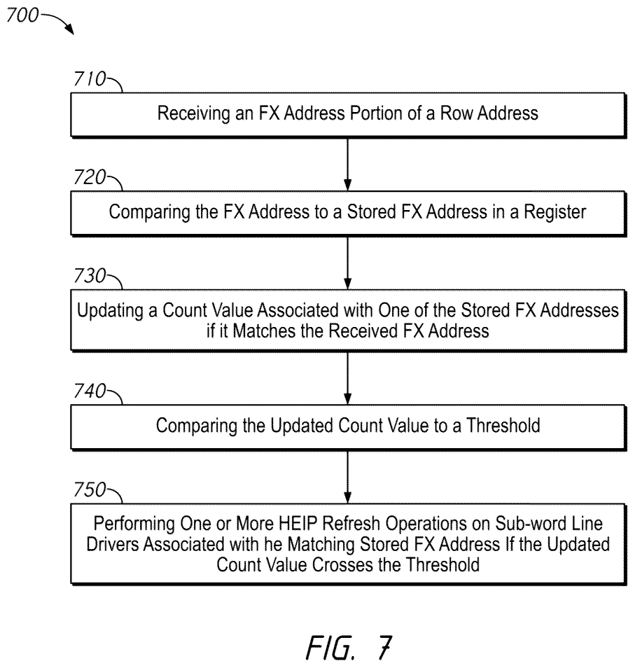

FIG. 7 is a flow chart of a method of tracking HEIP degradation according to some embodiments of the present disclosure. The method 700 may, in some embodiments, be implemented by one or more of the apparatuses, systems, or portions thereof described herein. For example, the method 700 may be implemented by the HEIP tracking circuit 142 of FIG. 1 and/or 420 of FIG. 4 in some embodiments.

The method 700 may begin with box 710, which describes receiving an FX address portion of a row address. For example, the row decoder (e.g., 108 of FIG. 1) may provide a row address which includes an FX portion and an MWL portion. The method may include receiving the row address as part of an operation on a memory bank.

Box 710 is followed by box 720, which describes comparing the FX address to a plurality of stored FX addresses in a register (e.g., 422 of FIG. 4). Box 720 may be followed by box 730, which describes updating a count value associated with one of the stored FX addresses if it matches the received FX address. The method 700 may include adding the FX address to the register if there is not a match. The method 700 may include overwriting one of the stored addresses associated with a lowest count value if the register is full.

The method 700 may include updating the count value by incrementing the count value. The method 700 may include updating the count value by an amount based on a measured temperature of the memory. The method 700 may include updating the count value each time a period of time elapses. The method 700 may include updating the count value by an amount based on a measured temperature each time a period of time elapses.

Box 730 may be followed by box 740, which describes comparing the count value to a threshold. Box 740 may be followed by box 750, which describes performing one or more HEIP refresh operations on sub-word line drivers (e.g., 210 of FIG. 2 and/or 320 of FIG. 3) associated with the matching stored FX address if the updated count value crosses the threshold.

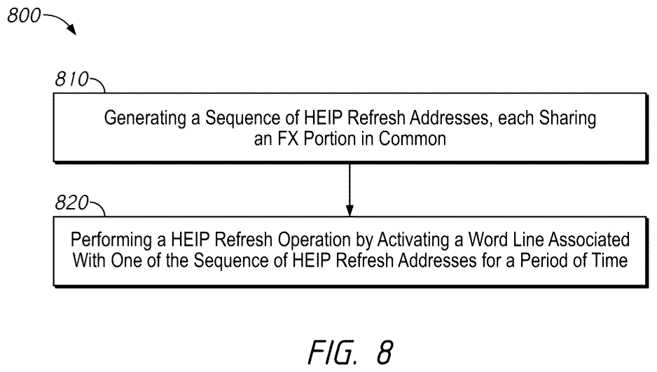

FIG. 8 is a flow chart of a method of performing HEIP refresh operations according to some embodiments of the present disclosure. The method 800 may, in some embodiments, be implemented by one or more of the apparatuses, systems, or portions thereof described herein. For example, the method 800 may be implemented by the HEIP mitigation circuit 144 of FIG. 1 and/or 430 of FIG. 4 in some embodiments.

The method 800 of FIG. 8 may involve performing HEIP refresh operations based on the FX address identified by a HEIP tracking circuit, such as described in method 700 of FIG. 7.

The method 800 starts with box 810, which describes generating a sequence of HEIP refresh addresses, each sharing an FX portion in common. For example, with a HEIP refresh address generator (e.g., 432 of FIG. 4). The method 800 may include generating a plurality of HEIP refresh addresses, each of which has a same FX portion but a different one of a plurality of MWL portions.

Box 810 may be followed by box 820, which describes performing a HEIP refresh operation by activating a word line associated with one of the sequence of HEIP refresh operations for a period of time. For example, the row decoder may activate the sub-word line driver associated with one of the HEIP refresh addresses. The period of time may be tRFC or longer. In some embodiments, the method 800 may include performing two HEIP refresh operations at a same time.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array comprising a plurality of word lines;
a plurality of sub-word line drivers each coupled to a respective one of the plurality of word lines, wherein sets of the sub-word line drivers are coupled to a common FX driver signal, wherein the FX signal is associated with an FX address; and
a refresh control circuit comprising a register configured to store a plurality of stored FX addresses and a plurality of count values each associated with one of the FX signals, wherein the refresh control circuit is configured to perform hot-electron induced punch-through (HEIP) refresh operations on sub-word line drivers of a selected one of the sets of the sub-word line drivers when one of the plurality of count values crosses a threshold.

2. The apparatus of claim 1, further comprising a row decoder configured to provide a row address, wherein the row address includes the FX address,
wherein the refresh control circuit is configured to receive the FX address and compare the FX address to the stored FX addresses, and update one of the plurality of count values if the FX address matches the associated stored FX address.

3. The apparatus of claim 2, wherein the refresh control circuit is configured to update the one of the plurality of count values by incrementing the count value.

4. The apparatus of claim 1, wherein the refresh control circuit is configured to generate a sequence of HEIP refresh addresses, each matching a word line coupled to one of the sub-word line drivers of the selected one of the sets of the sub-word line drivers.

5. The apparatus of claim 1, wherein the refresh control circuit is configured to perform the HEIP refresh operations by activating each of the sub-word line drivers of the selected one of the sets of the sub-word line drivers for at least a period of time.

6. The apparatus of claim 5, wherein the period of time is about tRFC or longer.

7. A method comprising:
receiving an FX address portion of a row address;
comparing the FX address to a plurality of stored FX addresses in a register;
updating a count value associated with one of the stored FX addresses if the one of the stored FX addresses matches the FX address;
comparing the updated count value to a threshold; and
performing one or more hot electron induced punch-through (HEIP) refresh operations on sub-word line drivers associated with the matching FX address if the updated count value crosses the threshold.

8. The method of claim 7, further comprising performing the one or more HEIP refresh operations by activating each of the sub-word line drivers associated with the FX address.

9. The method of claim 8, further comprising activating the each of the sub-word line drivers for about tRFC or longer.

10. The method of claim 7, further comprising adding the FX address to the register if it does not match one of the stored plurality of FX addresses.

11. The method of claim 10, further comprising replacing one of the stored plurality of FX addresses associated with the lowest count value with the FX address if the register is full.

12. The method of claim 7, further comprising updating the count value by more than one.

13. The method of claim 7, further comprising updating the count value by an amount based on a measured temperature.

14. An apparatus comprising:
a memory array comprising a plurality of word lines;
a plurality of sub-word line drivers, each coupled to one of the plurality of word lines, wherein sets of the plurality of sub-word line drivers are coupled to a respective one of a plurality of FX signals; and
a refresh control circuit configure to perform hot electron induced punch-through (HEIP) refresh operations by activating each of the plurality of sub-word line drivers associated with a selected one of the plurality of FX signals for a period of time each.

15. The apparatus of claim 14, wherein the period of time is about tRFC or longer.

16. The apparatus of claim 14, wherein the refresh control circuit is configured to activate two or more of the plurality of sub-word line drivers associated with the selected one of the plurality of FX signals at the same time.

17. The apparatus of claim 14, wherein the refresh control circuit is configured to provide a plurality of HEIP refresh addresses each of which have the selected one of the plurality of FX signals and each of a plurality of main word line (MWL) signals.

18. The apparatus of claim 14, wherein the refresh control circuit comprises a register configured to store a plurality of stored FX addresses and a plurality of count values each associated with one of the FX signals, wherein the refresh control circuit is configured to update one of the plurality of count values when a received FX address matches the associated one of the stored FX addresses.

19. A method comprising:
generating a sequence of hot electron induced punch-through (HEIP) refresh addresses, wherein each of the sequence of HEIP refresh addresses share an FX portion in common; and
performing an HEIP refresh operation by activating a word line associated with one of the sequence of HEIP refresh addresses for a period of time.

20. The method of claim 19, wherein the period of time is about tRFC or longer.

21. The method of claim 19, further comprising performing the HEIP refresh operation while performing one or more other refresh operations.

22. The method of claim 19, further comprising performing two or more HEIP refresh operations at a same time.

23. The method of claim 14, further comprising:
receiving an FX address portion of a row address;
comparing the FX address to a plurality of stored FX addresses;
updating a count value associated with one of the plurality of stored FX addresses, if the one of the plurality of stored FX addresses matches the FX address; and
selecting the selected one of the plurality of FX signals based on the one of the plurality of stored FX addresses if the count value crosses a threshold.

24. An apparatus comprising:
a p-type transistor;
a hot electron induced punch-through (HEIP) tracking circuit configured to determine if the p-type transistor has undergone HEIP degradation; and
a HEIP mitigation circuit configured to activate the p-type transistor identified as having undergone HEIP degradation for a period of time as part of a HEIP refresh operation.

25. The apparatus of claim 24, wherein the HEIP mitigation circuit is configured to perform the HEIP refresh operation by applying a low voltage to a gate of the p-type transistor for the period of time.

26. The apparatus of claim 24, wherein the period of time is about tRFC or longer.

27. The apparatus of claim 24, further comprising a voltage line coupled to the p-type transistor, wherein the HEIP tracking circuit is configured to determine if the p-type transistor has undergone HEIP degradation based on a number of times voltage is applied to the voltage line.

28. The apparatus of claim 24, wherein the p-type transistor is part of a sub-word line driver.
